(19) United States
(12) Patent Application Publication
(10) Pub. No.: US 2017/0006696 A1
(43) Pub. Date: Jan. 5, 2017

(54) HEAT DISSIPATION DEVICE FOR ELECTRONIC SYSTEM

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: JIN-SHAN MA, Shenzhen (CN); WEN-HAO DAI, Shenzhen (CN); WAN-LI NING, Shenzhen (CN)

(21) Appl. No.: 14/754,913

(22) Filed: Jun. 30, 2015

(51) Int. Cl. H05K 1/02

(52) U.S. Cl. CPC H05K 1/0203; H05K 2201/066; H05K 2201/2072

(57) ABSTRACT

An electronic system includes an electronic component, a heat dissipation device coupled on the electronic component and a retaining device around the electronic component. The heat dissipation device includes a base configured to contact the electronic component and a plurality of fins extending from the base. The base includes a coupling face forming a plurality of screw threads thereon. The retaining device includes at least a coupling face. The coupling face of the retaining device forms a plurality of screw threads for engaging with the screw threads of the coupling face of the base.

### FIELD

The subject matter herein generally relates to electronic systems, particularly relates to electronic systems with heat dissipation device.

### BACKGROUND

Electronic systems can include one or more electronic components. During operation of the electronic system, the electronic components can generate heat. The heat can change the performance of the electronic component. Heat removal components are often implemented to remove or transfer the heat from the electronic component.

### BRIEF DESCRIPTION OF THE DRAWINGS

Implementations of the present technology will now be described, by way of example only, with reference to the attached figures.

FIG.1 is an assembled, isometric view of an electronic system in accordance with a first embodiment of the present disclosure.

FIG. 2 is an exploded, isometric view of the electronic system of FIG. 1.

FIG. 3 is similar to FIG. 2, but viewed from a different angle.

FIG. 4 is a partially assembled view of the electronic system of FIG. 2.

FIG. 5 is an exploded, isometric view of an electronic system in accordance with a second embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to an electronic system. The electronic system can include an electronic component, a heat dissipation device located on the electronic component and a retaining device around the electronic component. The heat dissipation device can include a base for contacting the electronic component and a plurality of fins extending from the base. The base can include a coupling face forming a plurality of screw threads thereon. The retaining device includes at least a coupling face toward the coupling face of the base. The coupling face of the retaining device forms a plurality of screw threads for engaging with the screw threads of the coupling face of the base.

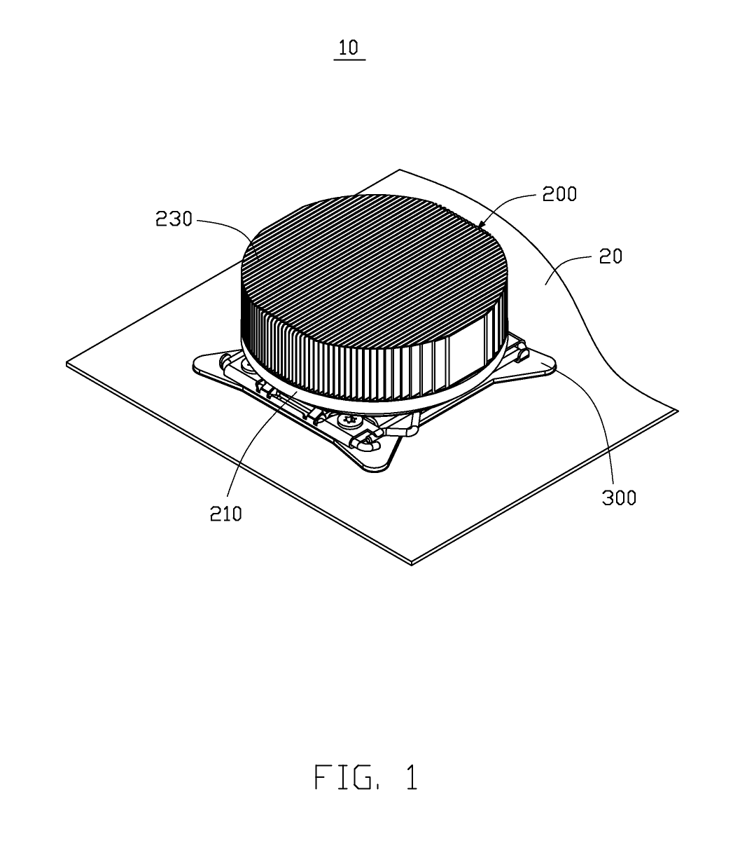

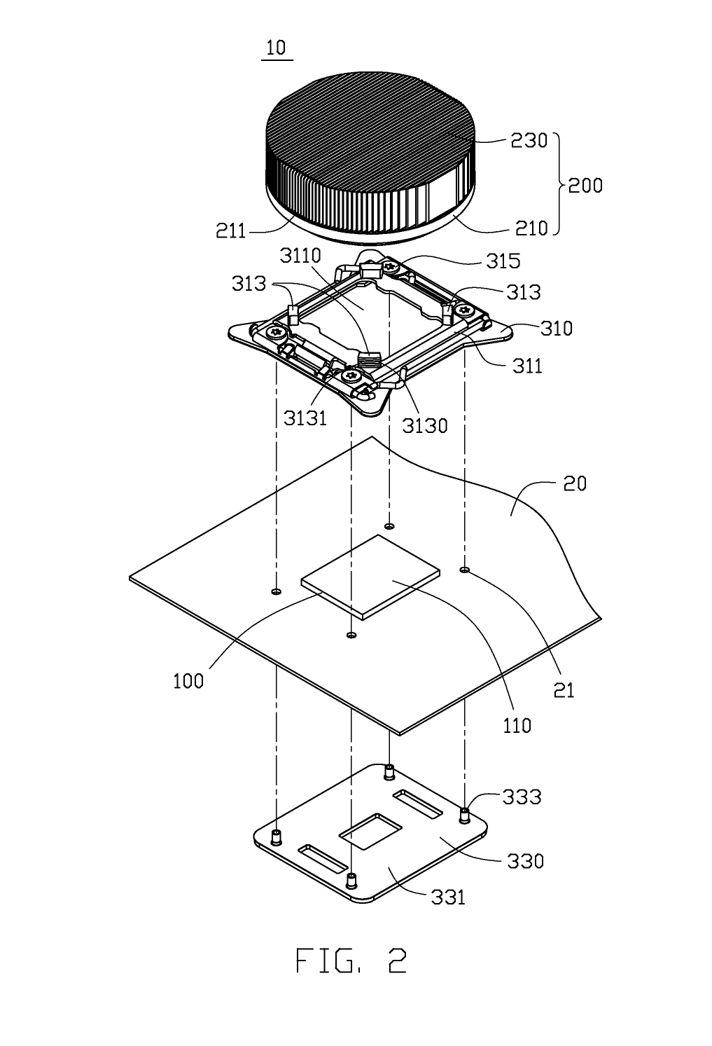

FIG. 1 illustrates an electronic system 10 of a first embodiment of the present disclosure. The electronic system 10 can include an electronic component 100 (shown in FIG. 2), a heat dissipation device 200 located on the electronic component 100, and a retaining device 300 for retaining the heat dissipation device 200 to the electronic component 100. In at least one embodiment, the electronic component 100 can be a CPU located on a printed circuit board 20.

FIG. 2 illustrates that the electronic component 100 includes a mounting face facing the printed circuit board 20 and a contacting face 110 facing the heat dissipation device 200.

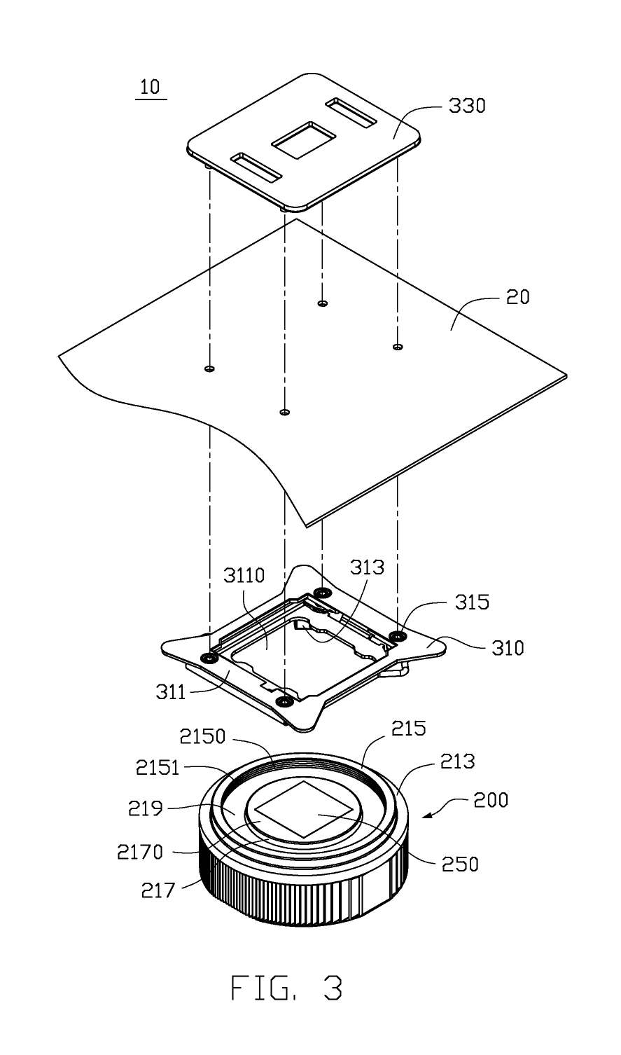

FIG. 3 illustrates that the heat dissipation device 200 includes a base 210 and a plurality of fins 230 extending from a face of the base 210. The base 210 includes a first face 211 (shown in FIG. 2) and a second face 213 opposite to the first face 211. The fins 230 extend from the first face 211. The base 210 further includes a circular flange 215 that extends outward from the second face 213 toward the retaining device 300. The flange 215 includes a coupling face 2150 for coupling the retaining device 300. The flange 215 forms a plurality of screw threads 2151 in the coupling face 2150. The coupling face 2150 is an inner face of the flange 215. The base 210 further extends a coupling platform 217 from a center portion of the second face 213 toward the electronic component 100. The platform 217 is spaced from and surrounded by the flange 215. An annular receiving groove 219 is defined between the flange 215 and the platform 217. The flange 215 extends beyond the platform 217 in a direction toward the printed circuit board 20. The platform 217 includes a contacting face 2170 for contacting the contacting face 110 of the electronic component 100. In at least one embodiment, the heat dissipation device 200 can further include a thermal interface 250 positioned on the contacting face 2170 of the platform 217. The base 210 can be in a shape of cylinder. The platform 217 can be in a shape of cylinder. The fins 230 can be parallel to each other. The fins 230 cooperatively define a cylinder configuration. The heat dissipation device 200 can further include at least a heat pipe located between the base 210 and the fins 230 for transferring heat from the base 210 to the fins 230.

FIG. 2 and FIG. 3 illustrate that the retaining device 300 can include a retaining member 310 located on the printed circuit board 20 and surrounding the electronic component 100. The retaining device 300 can further include a backplate 330 located below the printed circuit board 20 for retaining the retaining member 310 on the circuit board 20. The retaining member 310 can include a base plate 311 and a plurality of coupling blocks 313 extending from the base plate 311 toward the heat dissipation device 200. The coupling blocks 313 are substantially perpendicular to the base plate 311. The base plate 311 defines a through opening 3110 in central portion thereof for exposing the electronic component 100. The base plate 311 can be substantially rectangular. The opening 3110 can be substantially rectangular. The plurality of coupling blocks 313 are spaced apart from each other and around the opening 3110.

In at least one embodiment, the plurality of coupling blocks 313 can number four. When there are four coupling blocks 313, the four coupling blocks 313 can be located at four corners of the base plate 311. Each of the coupling blocks 313 has a coupling face 3130 for coupling the flange 215. Each of the coupling blocks 313 forms a plurality of screw threads 3131 in the coupling face 3130. The coupling faces 3130 of the four coupling blocks 313 are located on a circumferential face of an imaginary cylinder. In at least one embodiment, each of the four coupling blocks 313 is arched. The four coupling blocks 313 can cooperatively define the imaginary cylinder. For example, the coupling faces 3130 are located in an outer circumferential face of the imaginary cylinder.

The base plate 311 further includes a plurality of coupling members 315 extending toward the printed circuit board 20. The backplate 330 includes a main portion 331 and a plurality of coupling poles 333 extending from the main portion 331 toward the coupling members 315.

The circuit board 20 can define a plurality of through apertures 21 corresponding to the coupling poles 333 of the backplate 330.

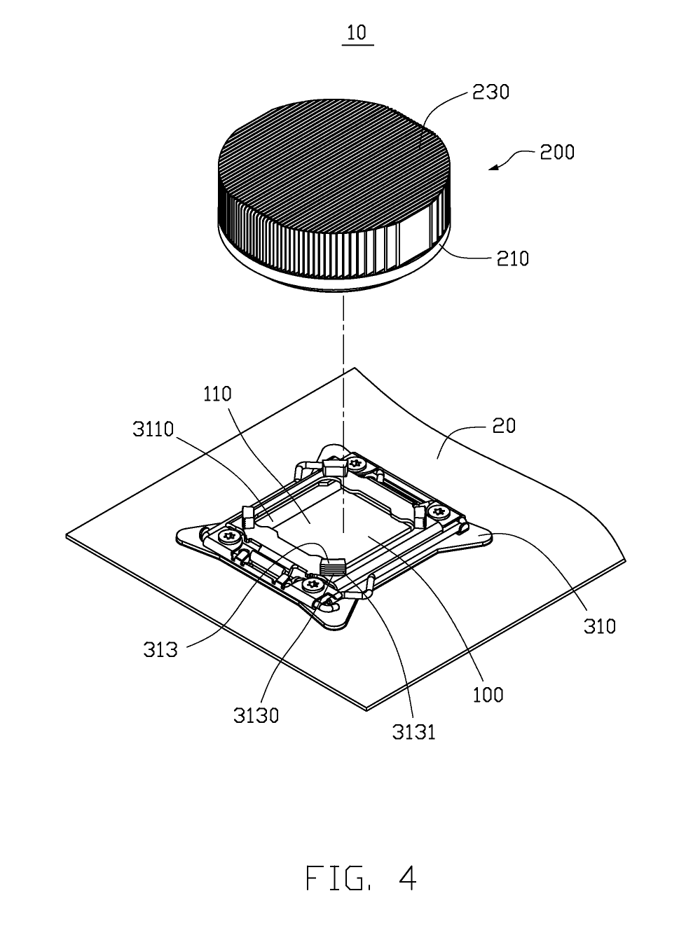

FIG. 1 and FIG. 4 illustrate that, in an assembly, the electronic component 100 is positioned on the printed circuit board 20. The retaining member 310 of the retaining device 300 is positioned on the printed circuit board 20 and has the electronic component 100 exposed outwards via the opening 3110. The backplate 330 (shown in FIG. 3) of the retaining device 300 is coupled to a face of the printed circuit board 20 opposite to the retaining member 310. The coupling poles 333 (shown in FIG. 2) extend through the through apertures 21 (shown in FIG. 2) and engage with coupling members 315 (shown in FIG. 2) of the retaining member 310, whereby, the retaining member 310 is retained to the printed circuit board 20 by the coupling poles 333. The electronic component 100 can be retained on the printed circuit board 20 by the retaining member 310.

The heat dissipation device 200 is positioned on the electronic component 100. The platform 217 (shown in FIG. 3) of the base 210 of the heat dissipation device 200 is located on the electronic component 100. The flange 215 (shown in FIG. 3) of the base 210 surrounds the coupling blocks 313 of the retaining member 310. The coupling blocks 313 are received in the receiving groove 219 (shown in FIG. 3) of the heat dissipation device 200. The coupling face 2150 (shown in FIG. 3) of the flange 215 (shown in FIG. 3) faces the coupling faces 3130 of the coupling blocks 313. The screw threads 2151 (shown in FIG. 3) in the coupling face 2150 engage with the screw threads 3131 in the coupling faces 3130. The contacting face 2170 (shown in FIG. 3) of the platform 217 (shown in FIG. 3) of the heat dissipation device 200 contacts the contacting face 110 of the electronic component 100. In at least one embodiment, the contacting face 2170 of the platform 217 can be in direct physical contact with the contacting face 110 of the electronic component 100. In at least one embodiment, the thermal interface 250 can be located between the contacting face 2170 of the platform 217 and the contacting face 110 of the electronic component 100.

In use, the electronic component 100 generates heat, the heat is absorbed by the platform 217 of the base 210 and is transferred to the fins 230. The fins 230 dissipate the heat to ambient air.

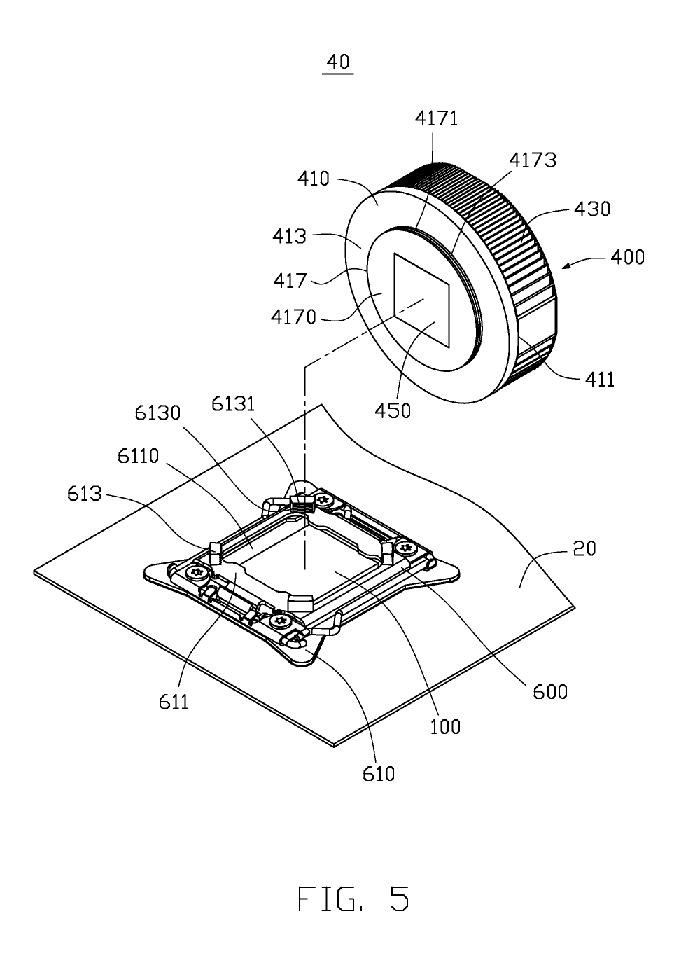

FIG. 5 illustrates an electronic system 40 of a second embodiment of the present disclosure. The electronic system 40 has a configuration similar to that of the electronic system 10 of the first embodiment. The electronic system 40 includes the electronic component 100 as illustrated in the first embodiment, a heat dissipation device 400 located on the electronic component 100, and a retaining device 600 around the electronic component 100. The electronic component 100 is located on the printed circuit board 20 as illustrated in the first embodiment.

The heat dissipation device 400 can include a base 410 and a plurality of fins 430 extending from a face of the base 410. The base 410 includes a first face 411 and a second face 413 opposite to the first face 411. The fins 430 extend from the first face 411. A coupling platform 417 extends from a center portion of the second face 413 toward electronic component 100. The platform 417 includes a contacting face 4170 for contacting the contacting face 110 of the electronic component 100. The platform 417 further includes a coupling face 4171 for coupling the platform 417 to the retaining device 600. The coupling face 4171 is an outer face of the platform 417. The platform 417 forms a plurality of screw threads 4173 on the coupling face 4171. In at least one embodiment, the heat dissipation device 400 can further include a thermal interface 450 positioned on the contacting face 4170 of the platform 417. The base 410 can be in a shape of cylinder. The platform 417 can be in a shape of cylinder. In at least one embodiment, the coupling face 4171 is an outer circumferential face of the platform 417. The fins 430 can be parallel to each other. The fins 430 cooperatively define a cylinder configuration.

The retaining device 600 can include a retaining member 610 located on the circuit board 20 and can surround the electronic component 100. The retaining device 600 can further include the backplate 330 (shown in FIG. 2) located below the circuit board 20 for locking the retaining member 610 on the circuit board 20. The retaining member 610 can include a base plate 611 and a plurality of coupling blocks 613 extending from the base plate 611 toward the heat dissipation device 400. The base plate 611 defines a through opening 6110 in central portion thereof for exposing the electronic component 100. The base plate 611 can be substantially rectangular. The opening 6110 can be substantially rectangular. The plurality of coupling blocks 613 are spaced from each other and around the opening 6110. In at least one embodiment, the plurality of coupling blocks 613 can number four and be located at four corners of the base plate 611. Each of the coupling blocks 613 has a coupling face 6130 for coupling the platform 417. Each of the coupling blocks 613 forms a plurality of screw threads 6131 in the coupling face 6130. The coupling faces 6130 of the four coupling blocks 613 are located on a circumferential face of an imaginary cylinder. In at least one embodiment, each of the four coupling blocks 613 is arched. The four coupling blocks 613 can cooperatively define the imaginary cylinder. In at least one embodiment, the coupling faces 6130 are located on an inner face of the imaginary cylinder. The coupling faces 6130 are located on an inner circumferential face of the imaginary cylinder.

It can be understood that, in an assembly, the electronic component 100 is positioned on the printed circuit board 20, the retaining member 610 of the retaining device 600 is coupled on the printed circuit board 20 and has the electronic component 100 exposed outwards via the opening 6110. The backplate 330 of the retaining device 600 is positioned to a face of the printed circuit board 20 opposite to the retaining member 610. The backplate 330 is engaged with the retaining member 610, whereby, the retaining member 610 is retained to the printed circuit board 20. The electronic component 100 can be retained on the printed circuit board 20 by the retaining member 610. The heat dissipation device 400 is positioned on the electronic component 100. The platform 417 of the base 410 of the heat dissipation device 400 is located on the electronic component 100. The platform 417 of the base 410 is surrounded by the coupling blocks 613 of the retaining member 610. The coupling face 4171 of the platform 417 faces the coupling faces 6130 of the coupling blocks 613. The screw threads 4173 in the coupling face 4171 engage with the screw threads 6131 in the coupling faces 6130. The contacting face 4170 of the platform 417 of the heat dissipation device 400 contacts the contacting face 110 of the electronic component 100. In at least one embodiment, the contacting face 4170 of the platform 417 can be in direct physical contact with the contacting face 110 of the electronic component 100. In at least one embodiment, the thermal interface 450 can located between the contacting face 4170 of the platform 417 and the contacting face 110 of the electronic component 100.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An electronic system comprising:
an electronic component;
a heat dissipation device coupled on the electronic component, the heat dissipation device comprising a base configured to contact the electronic component and a plurality of fins extending from the base, wherein the base comprises a coupling face forming a plurality of screw threads thereon; and
a retaining device positioned around the electronic component and comprising at least a coupling face, the coupling face of the retaining device forming a plurality of screw threads for engaging with the screw threads of the coupling face of the base.

2. The electronic system of claim 1, wherein the retaining device comprises a plurality of coupling blocks extending toward the heat dissipation device, the coupling face of the retaining device being a face of each of the coupling blocks.

3. The electronic system of claim 2, wherein the retaining device further comprises a base plate, the plurality of coupling blocks extending from the base plate, the base plate defining an opening exposing the electronic component outwards.

4. The electronic system of claim 3, wherein the plurality of coupling blocks are positioned around the opening.

5. The electronic system of claim 3, wherein the coupling faces of the coupling blocks positioned located on a circumferential face of an imaginary cylinder.

6. The electronic system of claim 5, wherein each of the coupling blocks is arched.

7. The electronic system of claim 5, wherein the coupling faces of the coupling blocks are outer faces of the coupling blocks.

8. The electronic system of claim 7, wherein the coupling face of the base is an inner face of the base.

9. The electronic system of claim 8, wherein the base comprises a flange extending toward the coupling blocks, the coupling face of the base is an inner face of the flange.

10. The electronic system of claim 9, wherein the base further comprises a platform extending toward and contacting the electronic component.

11. The electronic system of claim 10, wherein the flange surrounds the platform, a groove being defined between the flange and the platform for receiving the coupling blocks.

12. The electronic system of claim 5, wherein the coupling faces of the coupling blocks are inter faces of the coupling blocks.

13. The electronic system of claim 12, wherein the coupling face of the base is an outer face of the base.

14. The electronic system of claim 13, wherein the base comprises a platform extending toward and contacting the electronic component, the coupling face of the base being an outer face of the platform.

15. An electronic system comprising:
an electronic component located on a printed circuit board;
a heat dissipation device located on the electronic component, the heat dissipation device comprising a base contacting the electronic component and a plurality of fins extending from the base, the base comprising a coupling face with a plurality of screw threads thereon; and
a retaining device located around the electronic component and on the printed circuit board, the retaining device comprising at least a coupling face toward the coupling face of the base, the coupling face of the retaining device forming a plurality of screw threads engaging with the screw threads of the coupling face of the base.

16. The electronic system of claim 15, wherein the retaining device comprises a retainer located on the printed circuit board and a backplate located below the printed circuit board engaging with the retainer, the retainer extending a plurality of coupling blocks toward the base of the heat dissipation device.

17. The electronic system of claim 16, wherein the coupling blocks are spaced from each other, the coupling face of the retaining device being a face of each of the coupling blocks.

18. The electronic system of claim 17, wherein the coupling faces of the coupling blocks are located in a circumferential face of an imaginary cylinder.

19. The electronic system of claim 18, wherein each of the coupling blocks are arched, the coupling blocks cooperatively defining the imaginary cylinder.
